(19) United States
(12) Patent Application Publication
(10) Pub. No.: US 2026/0358376 A1
(43) Pub. Date: Nov. 12, 2026

(54) PROBE CARD DEVICE AND TRANSITION SUBSTRATE THEREOF

(71) Applicant: Silicon Future Manufacturing Company Ltd., Zhubei City (TW)

(72) Inventors: WEN-TSUNG SUNG, Zhubei City (TW); CHIA-HSIANG YU, Zhubei City (TW); YOU-CHEN LIN, Zhubei City (TW); YU-CHIEN CHEN, Zhubei City (TW); CHENG-CHUN WU, Zhubei City (TW); CHIH-WEI WEI, Zhubei City (TW)

(21) Appl. No.: 19/721,039

(22) Filed: Jun. 26, 2026

(30) Foreign Application Priority Data
Jul. 18, 2025 (TW) 114127238

(51) Int. Cl. G01R 1/073

(52) U.S. Cl. CPC G01R 1/07378; G01R 1/07342

(57) ABSTRACT

A probe card device comprises: a circuit substrate having a circuit substrate surface; an interposer substrate having a first interposer substrate surface and a second interposer substrate surface opposite to the first interposer substrate surface, the interposer substrate being disposed on the circuit substrate surface and electrically connected to the circuit substrate via a plurality of interposer through-holes; a transition substrate disposed on the second interposer substrate surface and electrically connected to the interposer substrate through the plurality of interposer through-holes, the transition substrate comprising: a redistribution layer having a first transition substrate surface and a second transition substrate surface opposite to the first transition substrate surface; and a probe head including a probe substrate and a plurality of probes, wherein the plurality of probes are electrically connected to the interposer substrate.

### CROSS-REFERENCE TO RELATED APPLICATION

This application claims the priority benefit of Taiwan application serial no. 114127238 filed on Jul. 18, 2025. The entirety of the above-mentioned patent applications is hereby incorporated by reference herein and made a part of this specification.

### FIELD

The present invention relates to a probe card device, and more particularly to a probe card device capable of reducing manufacturing costs and a transition substrate applicable thereto.

### BACKGROUND

A probe card is a precision testing device used during the wafer testing phase in semiconductor manufacturing processes for conducting electrical tests. A conventional Vertical Probe Card (VPC) mainly comprises a circuit substrate, a multi-layer organic (MLO) substrate layer (formed by stacking multiple layers of organic material substrates such as phenolic resin, glass fiber, polyimide, epoxy resin, etc.), multiple film layers, and a plurality of probes, the circuit substrate, MLO substrate layer, and one or more film layers are sequentially stacked, and the plurality of probes are disposed on the film layer and electrically connected to the circuit substrate through the MLO substrate layer. The pitch between contact points on the conventional circuit substrate is limited by current manufacturing processes and can only be reduced to approximately 100 μm to 200 μm. Therefore, the MLO substrate layer is used for spatial transformation, and a fan-in type package is implemented through the film layer to further reduce the pitch from approximately 100 μm to 200 μm down to around 50 μm to 60 μm or even 40 μm, thereby matching the increasingly smaller pitch between contact points on the device under test.

However, both multi-layer organic fabrication technology and multi-layer film fabrication technology are associated with high manufacturing costs that are difficult to reduce to meet market demands. Therefore, there remains a need for a probe card device and a corresponding transition substrate capable of addressing the issue of excessively high costs in existing technologies.

### SUMMARY

To address the aforementioned issues, an embodiment of the present invention provides a probe card device, comprising: a circuit substrate having a circuit substrate surface; an interposer substrate having a first interposer substrate surface and a second interposer substrate surface opposite to the first interposer substrate surface, the interposer substrate being disposed on the circuit substrate surface and electrically connected to the circuit substrate via a plurality of interposer through-holes; a transition substrate disposed on the second interposer substrate surface and electrically connected to the interposer substrate through the plurality of interposer through-holes, the transition substrate comprising: a redistribution layer having a first transition substrate surface and a second transition substrate surface opposite to the first transition substrate surface, wherein the first transition substrate surface includes a plurality of first transition contacts configured to be electrically connected to the interposer substrate, and the second transition substrate surface includes a plurality of second transition contacts respectively and electrically connected to the plurality of first transition contacts; and a probe head comprising a probe substrate and a plurality of probes, wherein the probe substrate is disposed on the second transition substrate surface, the plurality of probes are positioned on the probe substrate, and the plurality of probes are electrically connected to the interposer substrate.

Another embodiment of the present invention provides a transition substrate, comprising: a high-rigidity layer having a first high-rigidity surface and a second high-rigidity surface opposite to the first high-rigidity surface; a redistribution layer having a first transition substrate surface and a second transition substrate surface opposite to the first transition substrate surface, wherein the redistribution layer is stacked on the second high-rigidity surface, and the high-rigidity layer has a plurality of circuit through-holes.

According to the probe card device and its applicable transition substrate of the present invention, since the interposer substrate includes a plurality of interposer through-holes that electrically connect the first interposer substrate surface to the second interposer substrate surface, and the probe card device further includes a transition substrate comprising a redistribution layer, the interposer substrate and the redistribution layer are electrically connected to each other, allowing the probes on the probe head to be electrically connected to the circuit substrate sequentially through the probe substrate, the transition substrate, and the redistribution layer. Therefore, the probe card device of the present invention can reduce manufacturing costs and enhance its commercial competitiveness.

### BRIEF DESCRIPTION OF THE DRAWINGS

FIG. 1 is a schematic diagram of a probe card device according to an embodiment of the present invention.

FIG. 2 is an enlarged cross-sectional schematic diagram of a partial structure of the probe card device according to the embodiment of FIG. 1.

FIG. 3 is a schematic diagram of the redistribution layer according to an embodiment of the present invention.

FIG. 4 is a schematic diagram of a probe card device according to another embodiment of the present invention.

FIG. 5 is a schematic diagram of a transition substrate according to another embodiment of the present invention.

FIG. 6 is an enlarged cross-sectional schematic diagram of a partial structure of the probe card device according to the embodiment of FIG. 4.

### DETAILED DESCRIPTION

Various embodiments will be described below, and those skilled people in the relevant technical field should readily understand the spirit and principles of the present invention by referring to the description in conjunction with the drawings. However, although certain specific embodiments are described herein as examples, these embodiments are merely illustrative and are not to be considered limiting or exhaustive in any respect. Therefore, for those skilled people in the relevant technical field, various modifications and variations of the present invention will be apparent and easily achievable without departing from the spirit and principles of the present invention.

In the various embodiments of the present invention, terms such as “up,” “down,” “left,” “right,” “front,” or “back” are used to describe the positional relationship between one component and another solely for illustrating the orientation shown in the drawings, and do not limit the actual positions. The orientation or arrangement of components in the device shown in the drawings is not restricted by any flipping or inversion of the device.

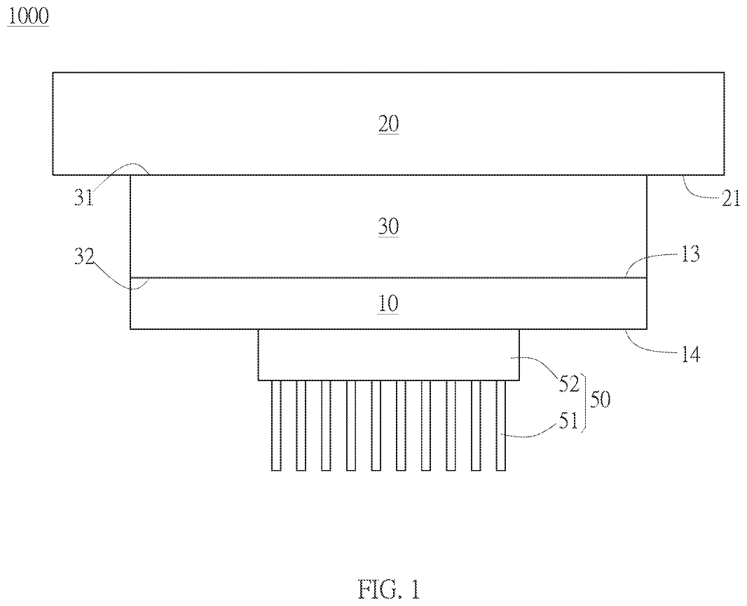

FIG. 1 is a schematic diagram of a probe card device according to an embodiment of the present invention. Referring to FIG. 1, the probe card device 1000 includes a circuit substrate 20, an interposer substrate 30, a transition substrate 10 which comprises a redistribution layer 110, and a probe head 50. The circuit substrate 20 can be a known printed circuit board, having a circuit substrate surface 21. The interposer substrate 30 includes epoxy resin, copper foil, or glass fiber, for example, made of FR-4 or FR-5 material, which has excellent insulation and high rigidity, serving as a sandwich layer between the circuit substrate 20 and the transition substrate 10 to enhance the overall rigidity of the probe card device 1000. The interposer substrate 30 has a first interposer substrate surface 31 and a second interposer substrate surface 32 opposite to the first interposer substrate surface 31. The interposer substrate 30 is disposed on the circuit substrate surface 21 of the circuit substrate 20 via the first interposer substrate surface 31 to be electrically connected to the circuit substrate 20. In this embodiment, the circuit substrate 20 functions as a test circuit substrate to provide test signals to the probe head 50. The interposer substrate 30 and the transition substrate 10 act as a space transformer for the probe card device 1000. The circuit substrate 20 connects, through the interposer substrate 30 and the transition substrate 10, to the multiple densely arranged probes 51 on the probe head 50.

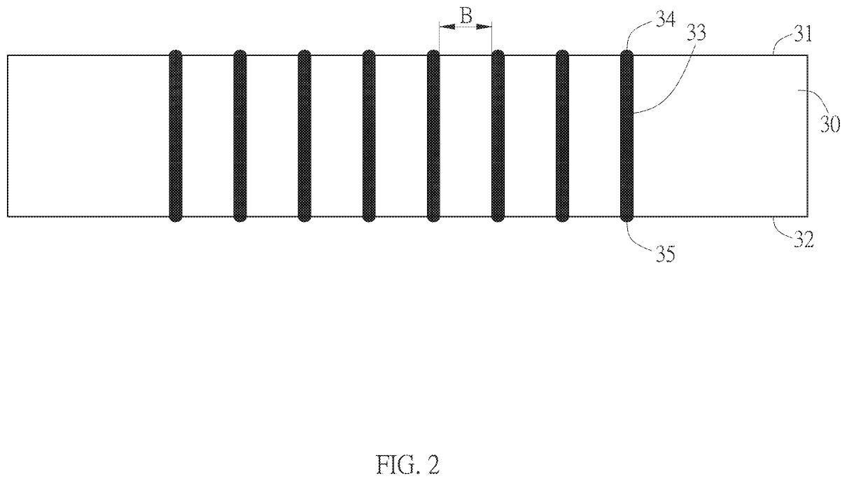

FIG. 2 is an enlarged cross-sectional schematic diagram of a partial structure of the probe card device according to the embodiment of FIG. 1. Please refer to FIGS. 1 and 2. The interposer substrate 30 further includes a plurality of interposer through-holes 33 that electrically connect the first interposer substrate surface 31 and the second interposer substrate surface 32. The interposer through-holes 33 can be in the form of plated through-holes (PTH), for example, formed by plating conductive metals such as copper onto vias pre-formed in the interposer substrate 30 through an electroplating process to achieve electrical conduction. In addition, the first interposer substrate surface 31 of the interposer substrate 30 has a plurality of first interposer contacts 34. The number of these first interposer contacts 34 corresponds to the number of the interposer through-holes 33, and each first interposer contact 34 is electrically connected to each interposer through-hole 33. The first interposer contacts 34 enable the interposer substrate 30 to electrically connect to the circuit substrate 20, wherein the spacing between any two adjacent first interposer contacts 34 is B. Furthermore, the second interposer substrate surface 32 has a plurality of second interposer contacts 35. The number of these second interposer contacts 35 also corresponds to the number of the interposer through-holes 33, and each second interposer contact 35 is electrically connected to each interposer through-hole 33. The second interposer contacts 35 enable the interposer substrate 30 to electrically connect to the transition substrate 10.

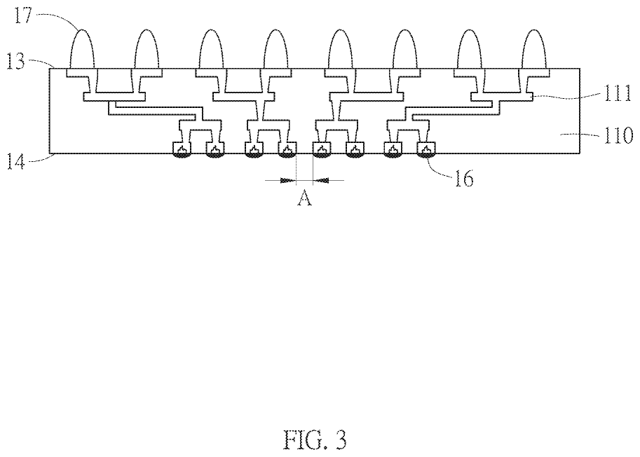

Please continue to refer to FIGS. 1 to 3. The transition substrate 10 includes a redistribution layer 110, which is disposed on the interposer substrate 30. The redistribution layer 110 has a first transition substrate surface 13 and a second transition substrate surface 14 opposite to the first transition substrate surface 13. The redistribution layer 110 uses a polymer film as the base material and is fabricated by a wafer-level redistribution layer process for fan-out packaging. Specifically, the original contact positions are rearranged through wafer-level metal wiring and bumping processes. For example, the redistribution layer 110 defines new circuit patterns using photolithography and then forms these new wiring pattern layers through processes such as electroplating and etching. More specifically, the redistribution layer 110 includes multiple inner lines 111, which are formed from conductive materials such as copper or gold. Additionally, the first transition substrate surface 13 has multiple first transition contacts 17, which are plated with metals like nickel or gold to maintain high conductivity. These first transition contacts 17 are electrically connected to at least one inner line 111 and serve to electrically connect the redistribution layer 110 to the second interposer contacts 35 of the interposer substrate 30. Furthermore, the second transition substrate surface 14 has multiple second transition contacts 16, which are electrically connected to at least one inner line 111 and serve to electrically connect the redistribution layer 110 to the probe head 50, wherein the spacing A between any two adjacent second transition contacts 16 ranges from 20 μm to 30 μm and is preferably smaller than the spacing B of the first interposer contacts 34 to accommodate the progressively shrinking contact pitch on the device under test (not shown) due to technological advancements.

Compared to conventional probe card devices, the probe card device 1000 of this embodiment includes an interposer substrate 30 and a transition substrate 10. The interposer substrate 30 is made of lower-cost materials such as FR-4 or FR-5, replacing the traditionally expensive MLO substrate layer or MLC substrate layer (multi-layer ceramic substrate). Moreover, the redistribution layer 110 included in the transition substrate 10 adopts a fan-out packaging structure to replace the traditionally costly fan-in packaging film layers, which reduces the manufacturing complexity during assembly between the interposer substrate 30 and the transition substrate 10. Therefore, the probe card device 1000 can significantly reduce manufacturing costs and thereby enhance its commercial competitiveness.

Please continue to refer to FIGS. 1 to 3. The probe head 50 includes a probe substrate 52 and a plurality of probes 51. The probe substrate 52 is disposed on the second transition substrate surface 14 of the redistribution layer 110. The redistribution layer 110 is electrically connected to the probe substrate 52 via the second transition contacts 16 on the second transition substrate surface 14. In addition, the probes 51 are positioned on the probe substrate 52 and extend in a direction away from the second transition substrate surface 14 of the redistribution layer 110. In this embodiment, the probe substrate 52 may be, for example, a circular or square microporous plate assembly made of Si3N4 or other machinable ceramics. The probes 51 are electrically connected to the circuit substrate 20 sequentially through the probe substrate 52, the redistribution layer 110, and the interposer substrate 30, so that the probes 51 can perform electrical testing on a device under test (not shown), and transmit electrical test signals from the circuit substrate 20 to the probes 51. In this embodiment, the main material of the probes 51 is typically a low-resistivity metal material such as copper, silver, gold, alloys thereof, or combinations thereof, but is not limited thereto. In addition, the surface of the probes 51 may optionally be coated with an inert conductive layer to prevent oxidation and extend service life. The inert conductive layer may be made of, for example, gold, platinum, silver, iridium, osmium, palladium, rhodium, ruthenium, or alloys or combinations thereof, but is not limited thereto. Furthermore, in this embodiment, the spacing between any two adjacent probes 51 is not particularly limited and may be adjusted based on the design and requirements of the contact points of the device under test.

Compared with conventional probe card devices, the probe card device provided by the present invention includes an interposer substrate having a plurality of interposer through-holes that electrically connect the second interposer substrate surface to the first transition substrate surface. Additionally, the probe card device further includes a transition substrate comprising a redistribution layer. The interposer substrate and the redistribution layer are arranged in conjunction with each other, allowing the probes on the probe head to be electrically connected to the circuit substrate in sequence through the probe substrate, the transition substrate, and the interposer substrate. Therefore, the probe card device of the present invention can reduce manufacturing costs and enhance the commercial competitiveness of the probe card device.

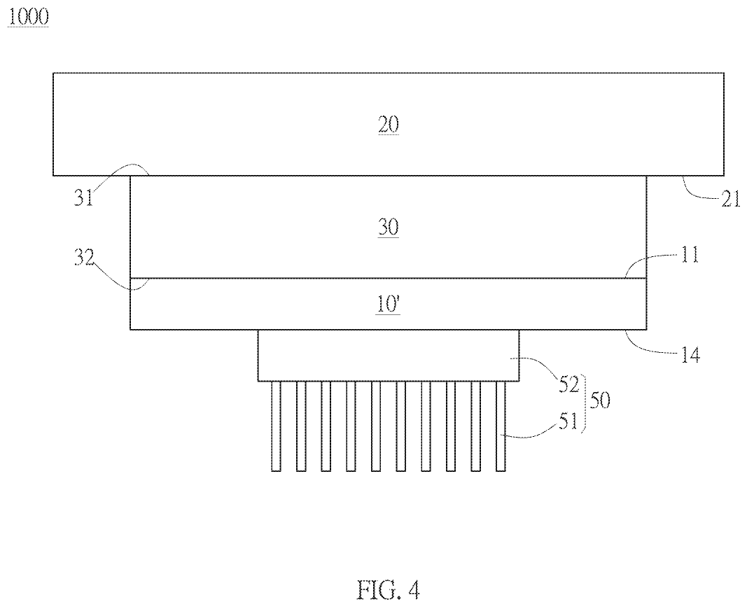

FIG. 4 is a schematic diagram of a probe card device according to an embodiment of the present invention. Referring to FIG. 4, the probe card device 1000 includes a circuit substrate 20, an interposer substrate 30, a transition substrate 10′ which comprises a redistribution layer 110, and a probe head 50. The circuit substrate 20 can be a known printed circuit board, having a circuit substrate surface 21. The interposer substrate 30 includes epoxy resin, copper foil, or glass fiber, for example, made of FR-4 or FR-5 material, which has excellent insulation and high rigidity, serving as a sandwich layer between the circuit substrate 20 and the transition substrate 10′ to enhance the overall rigidity of the probe card device 1000. The interposer substrate 30 has a first interposer substrate surface 31 and a second interposer substrate surface 32 opposite to the first interposer substrate surface 31. The interposer substrate 30 is disposed on the circuit substrate surface 21 of the circuit substrate 20 via the first interposer substrate surface 31 to be electrically connected to the circuit substrate 20. In this embodiment, the circuit substrate 20 functions as a test circuit substrate to provide test signals to the probe head 50. The interposer substrate 30 and the transition substrate 10′ act as a space transformer for the probe card device 1000. The circuit substrate 20 connects, through the interposer substrate 30 and the transition substrate 10, to the multiple densely arranged probes 51 on the probe head 50.

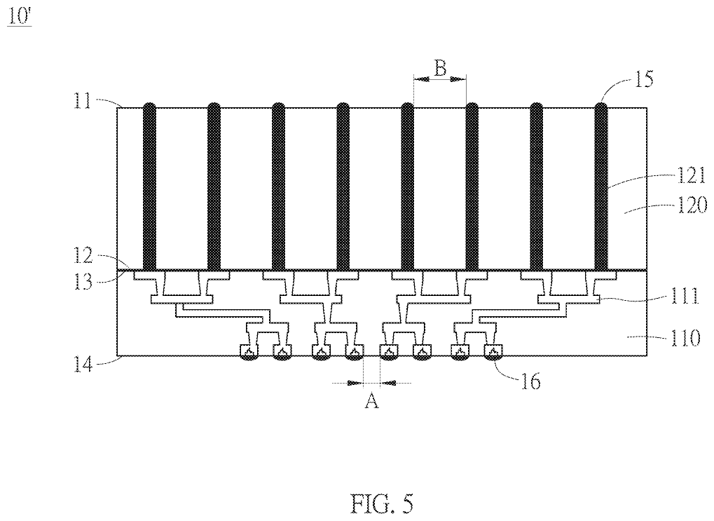

FIG. 5 is a schematic diagram of a transition substrate 10′ according to an embodiment of the present invention. Please refer to FIGS. 4 and 5. The transition substrate 10′ includes a high-rigidity layer 120 and a redistribution layer 110. The high-rigidity layer 120 has a first high-rigidity surface 11 and a second high-rigidity surface 12 opposite to the first high-rigidity surface 11. The high-rigidity layer 120 is composed of amorphous materials, such as glass, polystyrene, or other similar materials. The amorphous material has an elastic modulus in the range of 50-200 GPa and a shear modulus in the range of 25-80 GPa. By selecting materials with high strength, high rigidity, and excellent flatness, the high-rigidity layer 120 can better conform to the redistribution layer 110 during the fabrication of the transition substrate 10′. The redistribution layer 110 has a first transition substrate surface 13 and a second transition substrate surface 14 opposite to the first transition substrate surface 13. The redistribution layer 110 is stacked on the second high-rigidity surface 12 via the first transition substrate surface 13 and is electrically connected to the high-rigidity layer 120. The high-rigidity layer 120 includes a plurality of circuit through-holes 121, which extend through and connect the first high-rigidity surface 11 to the second high-rigidity surface 12. Since the transition substrate 10′ includes both the high-rigidity layer 120 and the redistribution layer 110, in contrast to conventional techniques in which the redistribution layer 110 is initially formed together with the high-rigidity layer 120 and the high-rigidity layer 120 is subsequently removed, the present invention retains the high-rigidity layer 120. Furthermore, by forming the circuit through-holes 121 in the high-rigidity layer 120, the high-rigidity layer 120 can be electrically connected to the redistribution layer 110. Therefore, the transition substrate 10′ can achieve the same technical effect as a structure that retains only the redistribution layer 110, while simplifying the manufacturing process by eliminating the need for rework. As a result, the yield of the transition substrate 10′ is improved, production costs are reduced, and commercial competitiveness is enhanced.

Referring again to FIG. 5, the high-rigidity layer 120 further includes a plurality of circuit through-holes 121 that electrically connect the first high-rigidity surface 11 to the second high-rigidity surface 12. The circuit through-holes 121 may be in the form of plated through-holes (PTH). For example, conductive materials such as copper, nickel, or gold can be plated into the pre-formed holes in the high-rigidity layer 120 through a plating process to establish electrical conductivity. Alternatively, the through-holes can be filled directly with metal pillars, conductive metals, conductive adhesive, or combinations of these materials. In addition, a plurality of high-rigidity contacts 15 is disposed on the first high-rigidity surface 11 of the high-rigidity layer 120. The number of the high-rigidity contacts 15 corresponds to the number of the circuit through-holes 121, and the high-rigidity contacts 15 are electrically connected to the plurality of interposer through-holes facing the first high-rigidity surface 11. These high-rigidity contacts 15 enable the transition substrate 10′ to be electrically connected to other circuit substrates (e.g., the interposer substrate 30). A spacing B is defined between any two adjacent high-rigidity contacts 15.

Referring again to FIG. 5, the redistribution layer 110 uses a polymer film as the base material and is fabricated by a wafer-level redistribution layer process for fan-out packaging. Specifically, the original contact positions are rearranged through wafer-level metal wiring and bumping processes. For example, the redistribution layer 110 defines new circuit patterns using photolithography and then forms these new wiring pattern layers through processes such as electroplating and etching. More specifically, the redistribution layer 110 includes multiple inner lines 111, which are formed from conductive materials such as copper or gold. A plurality of internal lines 111, on the side facing the first transition substrate surface 13, are electrically connected to the plurality of circuit through-holes 121, allowing the high-rigidity layer 120 and the redistribution layer 110 within the transition substrate 10′ to achieve improved electrical conduction. Additionally, the second transition substrate surface 14 has multiple second transition contacts 16, which are plated with metals like nickel or gold to maintain high conductivity. The second transition contacts 16 are electrically connected to at least one of the internal line 111 and serve to electrically connect the redistribution layer 110 to the probe head 50, wherein the spacing A between any two adjacent second transition contacts 16 ranges from 20 μm to 30 μm and is preferably smaller than the spacing B of the first interposer contacts 34 to accommodate the progressively shrinking contact pitch on the device under test (not shown) due to technological advancements.

Through the above-described embodiment, the transition substrate 10′ of the present invention includes both a high-rigidity layer 120 and a redistribution layer 110. Therefore, the transition substrate 10′ simultaneously provides the technical benefits of both the high-rigidity layer 120 and the redistribution layer 110. When applied to a probe card device, the printed circuit board of the probe card device (e.g., circuit substrate 20) can more effectively adhere to the first high-rigidity surface 11 of the transition substrate 10′. The second transition substrate surface 14 can be electrically connected to the probe head of the probe card device via the second transition contacts 16. Moreover, since the manufacturing of the transition substrate 10′ does not require rework, the yield of the transition substrate 10′ is correspondingly improved, thereby reducing production costs and enhancing the commercial competitiveness of the transition substrate 10′ when used in probe card devices.

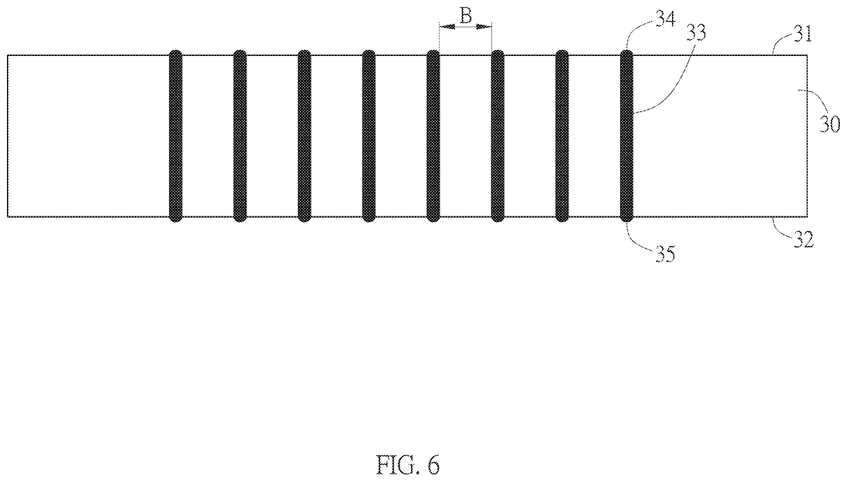

FIG. 6 is an enlarged cross-sectional schematic diagram of a partial structure of the probe card device according to the embodiment of FIG. 4. Please refer to FIGS. 4 and 6. The interposer substrate 30 further includes a plurality of interposer through-holes 33 that electrically connect the first interposer substrate surface 31 and the second interposer substrate surface 32. The interposer through-holes 33 can be in the form of plated through-holes (PTH), for example, formed by plating conductive metals such as copper onto vias pre-formed in the interposer substrate 30 through an electroplating process to achieve electrical conduction. In addition, the first interposer substrate surface 31 of the interposer substrate 30 has a plurality of first interposer contacts 34. The number of these first interposer contacts 34 corresponds to the number of the interposer through-holes 33, and each first interposer contact 34 is electrically connected to each interposer through-hole 33. The first interposer contacts 34 enable the interposer substrate 30 to electrically connect to the circuit substrate 20, wherein the spacing between any two adjacent first interposer contacts 34 is B. Furthermore, the second interposer substrate surface 32 has a plurality of second interposer contacts 35. The number of these second interposer contacts 35 also corresponds to the number of the interposer through-holes 33, and each second interposer contact 35 is electrically connected to each interposer through-hole 33. The second interposer contacts 35 enable the interposer substrate 30 to electrically connect to the transition substrate 10′.

Compared to conventional probe card devices, the probe card device 1000 of this embodiment includes an interposer substrate 30 and a transition substrate 10. The interposer substrate 30 is made of lower-cost materials such as FR-4 or FR-5, replacing the traditionally expensive MLO substrate layer or MLC substrate layer (multi-layer ceramic substrate). Moreover, the transition substrate 10′ replaces the conventional single fan-in type packaging film layer, and its fabrication does not require any rework, which reduces the manufacturing complexity during assembly between the interposer substrate 30 and the transition substrate 10′. Therefore, the probe card device 1000 can significantly reduce manufacturing costs and thereby enhance its commercial competitiveness.

Please continue to refer to FIGS. 4 to 6. The probe head 50 includes a probe substrate 52 and a plurality of probes 51. The probe substrate 52 is disposed on the second transition substrate surface 14 of the transition substrate 10′. The redistribution layer 110 is electrically connected to the probe substrate 52 via the second transition contacts 16 on the second transition substrate surface 14. In addition, the probes 51 are positioned on the probe substrate 52 and extend in a direction away from the second transition substrate surface 14 of the redistribution layer 110. In this embodiment, the probe substrate 52 may be, for example, a circular or square microporous plate assembly made of Si3N4 or other machinable ceramics. The probes 51 are electrically connected to the circuit substrate 20 sequentially through the probe substrate 52, the transition substrate 10′, and the interposer substrate 30, so that the probes 51 can perform electrical testing on a device under test (not shown), and transmit electrical test signals from the circuit substrate 20 to the probes 51. In this embodiment, the main material of the probes 51 is typically a low-resistivity metal material such as copper, silver, gold, alloys thereof, or combinations thereof, but is not limited thereto. In addition, the surface of the probes 51 may optionally be coated with an inert conductive layer to prevent oxidation and extend service life. The inert conductive layer may be made of, for example, gold, platinum, silver, iridium, osmium, palladium, rhodium, ruthenium, or alloys or combinations thereof, but is not limited thereto. Furthermore, in this embodiment, the spacing between any two adjacent probes 51 is not particularly limited and may be adjusted based on the design and requirements of the contact points of the device under test.

In summary, in the probe card device and its applicable transition substrate of the present invention, since the interposer substrate includes a plurality of interposer through-holes that electrically connect the first interposer substrate surface to the second interposer substrate surface, and the probe card device further includes a transition substrate that is disposed in conjunction with the interposer substrate, allowing the probes on the probe head to be electrically connected to the circuit substrate sequentially through the probe substrate, the transition substrate, and the redistribution layer. Therefore, the probe card device of the present invention can reduce manufacturing costs and enhance its commercial competitiveness.

The present invention has been described through the aforementioned embodiments; however, these embodiments are merely examples for implementing the invention. It should be noted that the disclosed embodiments do not limit the scope of the invention. On the contrary, modifications and equivalent arrangements that fall within the spirit and scope of the appended claims are all encompassed within the scope of the present invention.

1. A probe card device, comprising:
a circuit substrate having a circuit substrate surface;
an interposer substrate having a first interposer substrate surface and a second interposer substrate surface opposite to the first interposer substrate surface, the interposer substrate being disposed on the circuit substrate surface and electrically connected to the circuit substrate via a plurality of interposer through-holes;
a transition substrate disposed on the second interposer substrate surface and electrically connected to the interposer substrate through the plurality of interposer through-holes, the transition substrate comprising:
a redistribution layer having a first transition substrate surface and a second transition substrate surface opposite to the first transition substrate surface, wherein the first transition substrate surface includes a plurality of first transition contacts configured to be electrically connected to the interposer substrate, and the second transition substrate surface includes a plurality of second transition contacts respectively and electrically connected to the plurality of first transition contacts; and
a probe head comprising a probe substrate and a plurality of probes, wherein the probe substrate is disposed on the second transition substrate surface, the plurality of probes are positioned on the probe substrate, and the plurality of probes are electrically connected to the interposer substrate.

2. The probe card device of claim 1, wherein the redistribution layer is a fan-out packaging redistribution layer.

3. The probe card device of claim 1, wherein the interposer substrate comprises epoxy resin, copper foil, or glass fiber.

4. The probe card device of claim 1, wherein a spacing between any two adjacent second transition contacts among the plurality of second transition contacts is between 20 μm and 30 μm.

5. The probe card device of claim 1, wherein the transition substrate further comprises:
a high-rigidity layer having a first high-rigidity surface and a second high-rigidity surface opposite to the first high-rigidity surface;
wherein the redistribution layer is stacked on the second high-rigidity surface, and the high-rigidity layer is disposed on the second interposer substrate surface, the high-rigidity layer having a plurality of circuit through-holes; and wherein the plurality of circuit through-holes are electrically connected to the plurality of interposer through-holes.

6. A transition substrate, comprising:
a high-rigidity layer having a first high-rigidity surface and a second high-rigidity surface opposite to the first high-rigidity surface;
a redistribution layer having a first transition substrate surface and a second transition substrate surface opposite to the first transition substrate surface, wherein the redistribution layer is stacked on the second high-rigidity surface, and the high-rigidity layer has a plurality of circuit through-holes.

7. The transition substrate of claim 6, wherein the plurality of circuit through-holes are formed by a plated through-hole, or a metal pillar, a conductive metal, a conductive adhesive, or a combination thereof.

8. The transition substrate of claim 6, wherein the high-rigidity layer is composed of an amorphous material.

9. The transition substrate of claim 6, wherein the redistribution layer is a fan-out package redistribution layer.

10. The transition substrate of claim 6, further comprising:
a plurality of high-rigidity contacts, wherein the plurality of high-rigidity contacts are electrically connected to the plurality of circuit through-holes facing the first high-rigidity surface;
a plurality of second transition contacts, wherein the plurality of second transition contacts are disposed on the second transition substrate surface.

11. The transition substrate of claim 10, wherein the redistribution layer has a plurality of inner lines, one side of the plurality of inner lines electrically connected to the plurality of circuit through-holes, and the other side electrically connected to the plurality of second transition contacts.
